(19) United States
(12) Patent Application Publication
(10) Pub. No.: US 2011/0183493 A1
(43) Pub. Date: Jul. 28, 2011

(54) PROCESS FOR MANUFACTURING A STRUCTURE COMPRISING A GERMANIUM LAYER ON A SUBSTRATE

(75) Inventors: Nicolas Daval, Pleasantville, NY (US); Oleg Kononchuk, Grenoble (FR); Eric Guiot, Goncelin (FR); Cecile Aulnette, Guilderland, NY (US); Fabrice Lallement, Grenoble (FR); Christophe Figuet, Crolles (FR); Didier Landru, Champ Pres Froges (FR)

(73) Assignee: S.O.I.TEC SILICON ON INSULATOR TECHNOLOGIES, Crolles Cedex (FR)

(21) Appl. No.: 12/937,920

(22) PCT Filed: Jun. 12, 2009
(86) PCT No.: PCT/EP09/57293

§ 371 Date: Apr. 5, 2011

(30) Foreign Application Priority Data
Jul. 3, 2008 (FR) 0854510

(51) Int. Cl. H01L 21/762

(52) U.S. Cl. 438/458; 257/E21.568

(57) ABSTRACT

The present invention relates to a process for manufacturing a structure comprising a germanium layer (3) on a support substrate (1), characterised in that it comprises the following steps:
(a) formation of an intermediate structure (10) comprising said support substrate (1), a silicon oxide layer (20) and said germanium layer (3), the silicon oxide layer (20) being in direct contact with the germanium layer (3),
(b) application to said intermediate structure (10) of a heat treatment, in a neutral or reducing atmosphere, at a defined temperature and for a defined time, to diffuse at least part of the oxygen from the silicon oxide layer (20) through the germanium layer (3).

### CROSS-REFERENCE TO RELATED APPLICATIONS

This is a national phase entry under 35 U.S.C. §371 of International Patent Application PCT/EP2009/057293, filed Jun. 12, 2009, published in English as International Patent Publication WO 2010/000596 A1 on Jan. 7, 2010, which claims the benefit under Article 8 of the Patent Cooperation Treaty to French Patent Application Serial No. 08 54510, filed Jul. 3, 2008, the entire disclosure of each of which is hereby incorporated herein by this reference.

### TECHNICAL FIELD

The present invention relates to a process for manufacturing a structure comprising a germanium layer on a substrate.

### BACKGROUND

The manufacture of semiconductor layers comprising a germanium layer on a substrate—an insulating layer being optionally inserted between the germanium layer and the substrate—is particularly promising in the field of microelectronics, optoelectronics and photovoltaics.

Indeed, germanium has more advantageous electrical characteristics than those of silicon, particularly due to a greater mobility of the charges (electrons and holes) in this material.

In this way, germanium on insulator, also known as GeOI, structures may advantageously be used to form MOS transistors.

These structures are also advantageous for the production of photodetectors or solar cells in or on the germanium layer, by means of the narrowness of the forbidden band of germanium and the lattice parameter thereof compatible with the formation of additional active layers for example of AsGa, InP, etc.

Unlike a silicon on insulator (SOI) structure, wherein the insulating layer may be a silicon oxide layer, the insulating layer of a GeOI structure cannot be germanium oxide as this oxide is not sufficiently stable. Therefore, the insulating layer of a GeOI structure generally comprises silicon oxide (SiO₂) formed by deposition or by oxidation of the support substrate.

Furthermore, in photovoltaic applications, a heterostructure with a conducting interface, comprising a germanium layer on an inexpensive substrate, such as silicon, represents an economically advantageous alternative to a multi-layer structure formed on a germanium substrate, which is particularly expensive.

In any case, the germanium layer must have crystalline, electrical and morphological qualities suitable for proper operation of the components formed therewith.

The GeOI structures may be manufactured using a layer transfer technique known as Smart Cut™.

According to one embodiment of said process, a germanium layer is formed by means of epitaxy on a first substrate or a bulk germanium substrate is supplied, and a silicon oxide insulating layer is deposited on said germanium layer; ion implantation is then performed to form, in the substrate, under the germanium layer, an embrittlement zone. This structure is then bonded onto a second substrate, the SiO₂ layer being situated at the bonding interface, and, by means of a rupture of the first substrate along the embrittlement zone, the germanium layer is transferred to the second substrate.

However, GeOI structure having a germanium/silicon oxide interface obtained using known techniques currently have relatively unsatisfactory electrical properties, particularly with respect to the density of interface traps (DIT), typically of the order of 10¹² to 10¹³ eV⁻¹·cm⁻².

Indeed, since germanium is necessarily reactive with oxygen, a germanium oxide layer is formed, particularly at the interface between the germanium layer and the silicon oxide insulating layer, which impairs the electrical properties of the germanium layer.

In the case of an SOI, acceptable DIT values of the order of 10¹¹ Ev¹·cm⁻² are attained, which would also be desirable to obtain for a GeOI if said GeOI is intended for microelectronic applications, such as a CMOS component.

Different manufacturing processes have already been developed to improve the electrical quality of the germanium layer and/or the interface between the germanium layer and the insulating layer.

In this way, the document U.S. Pat. No. 7,229,898 envisages the creation of a passivation layer, for example made of germanium oxynitride (having the general formula GeOₓN_{y}), between the germanium layer and the insulating layer. Indeed, it was observed that the interface between the germanium layer and the germanium oxynitride layer had very good electrical properties.

The document WO 2007/045759 envisages the application of thermal annealing, at a temperature between 500 and 600° C. in a neutral atmosphere. This annealing results in a marked improvement in the quality of the interface between the germanium layer and the insulating layer. This improvement is particularly conveyed by a decrease in the DIT value.

Furthermore, when the Smart Cut™ process is used, the implantation damages the germanium over a much greater thickness than in the case of silicon.

These residual implantation defects, which impair the morphological and crystalline quality of the germanium layer, must be repaired by means of a heat treatment prior to the manufacture of components on or in this layer.

With respect to structures comprising a germanium layer on a substrate and having a conductive interface, without an insulating layer being inserted between the germanium layer and the substrate, reference may be made to the document WO 02/08425 which describes a process for forming such structures.

However, in the absence of a silicon oxide insulating layer, wherein the adherence properties make it possible to obtain good quality bonding, direct bonding of germanium on the substrate is problematic. Indeed, blisters are formed at the bonding interface which do not allow a satisfactory transfer of the germanium layer onto the substrate.

Therefore, one of the aims of the invention is to define a process for manufacturing a structure comprising a germanium layer on a substrate, optionally with an insulating layer between the germanium layer and the substrate, which makes it possible to improve the electrical qualities of such a structure.

This process should also facilitate the manufacture of said structure, and particularly enable satisfactory adhesion of the germanium layer on the substrate.

### BRIEF SUMMARY

According to the invention, a process for manufacturing a structure comprising a germanium layer on a support substrate is proposed, comprising the following steps:

(a) formation of an intermediate structure comprising said support substrate, a silicon oxide layer and said germanium layer, the silicon oxide layer being in direct contact with the germanium layer,

(b) application to said intermediate structure of a heat treatment, in a neutral or reducing atmosphere, at a defined temperature and for a defined time, to diffuse at least part of the oxygen from the silicon oxide layer through the germanium layer.

It is specified that, in the present document, the term “on” refers to the fact that a layer is situated on top of another in a given structure from the base to the surface thereof, it being understood that one or more layers may optionally be inserted between said layers. On the other hand, when two layers have a common surface, they are said to be “in direct contact”.

Preferentially, the heat treatment in step (b) is performed at a temperature between 800 and 900° C., and the oxygen content in the atmosphere of the treatment in step (b) is less than 1 ppm.

The thickness of the germanium layer is less than 500 nm, preferentially less than 100 nm.

The thickness of the silicon oxide layer of the intermediate structure is less than 6 nanometres, preferentially less than 2 nm, and, in step (b), all the oxygen from said layer diffuses through the germanium layer.

According to a first embodiment of the invention, step (a) comprises the following steps:

i) formation of the silicon oxide layer on the support substrate or on a germanium donor substrate,

ii) formation of an embrittlement zone in a germanium donor substrate, the embrittlement zone defining the germanium layer to be transferred,

iii) bonding of the germanium donor substrate on the support substrate, the silicon oxide layer being situated at the bonding interface,

iv) rupture of the germanium donor substrate along the embrittlement zone and transfer of the germanium layer onto the support substrate, so as to form said intermediate structure.

According to a second embodiment of the invention, step (a) comprises the following steps:

i) formation of the silicon oxide layer on the support substrate or on a germanium donor substrate,

ii) bonding of the germanium donor substrate on the support substrate, the silicon oxide layer being situated at the bonding interface,

iii) thinning of the germanium donor substrate so as to retain only the thickness of the germanium layer, thus forming said intermediate structure.

According to a third embodiment of the invention, step (a) comprises the following steps:

i) formation of a silicon on insulator type structure, comprising the support substrate, a silicon oxide layer and a silicon layer,

ii) deposition, on the silicon layer, of a SiGe layer,

iii) application of an oxidation heat treatment of said SiGe layer, resulting in the formation by condensation of a germanium layer on the silicon oxide layer and an upper silicon oxide layer on said germanium layer,

iv) removal of the upper silicon oxide layer, so as to form said intermediate structure.

A further aim of the invention relates to a structure comprising a germanium layer on a support substrate, comprising, between the support substrate and the germanium layer, a silicon layer in contact with the germanium layer, wherein the silicon layer has a thickness between 1 and 3 nanometres.

According to a particular embodiment of the invention, said structure comprises, between the support substrate and the silicon layer, a silicon oxide layer.

### BRIEF DESCRIPTION OF THE DRAWINGS

Other features and advantages of the invention will emerge from the detailed description hereinafter, with reference to the appended figures wherein:

FIG. 1 illustrates a germanium on insulator type intermediate structure,

FIG. 2 illustrates a germanium on insulator type structure according to the invention,

FIG. 3 illustrates another structure according to the invention, comprising a germanium layer on a support substrate, with a conductive interface,

FIGS. 4A and 4B represent steps of the manufacture of the intermediate structure using the Smart Cut™ process,

FIG. 5 represents a step of the manufacture of the intermediate structure by means of a bonding process followed by thinning,

FIGS. 6A to 6C illustrate steps of the manufacture of the intermediate structure by means of a condensation process.

It is specified that, to facilitate the comprehension of these figures, the respective scales of the thicknesses of the different layers were not observed.

### DETAILED DESCRIPTION OF THE INVENTION

Different possible embodiments to form a structure comprising a germanium layer 3 on a support substrate 1, wherein the electrical properties of the germanium layer and the interface between the germanium layer and the underlying layer are optimised, will now be described.

As a general rule, the process essentially comprises two successive steps, which are:

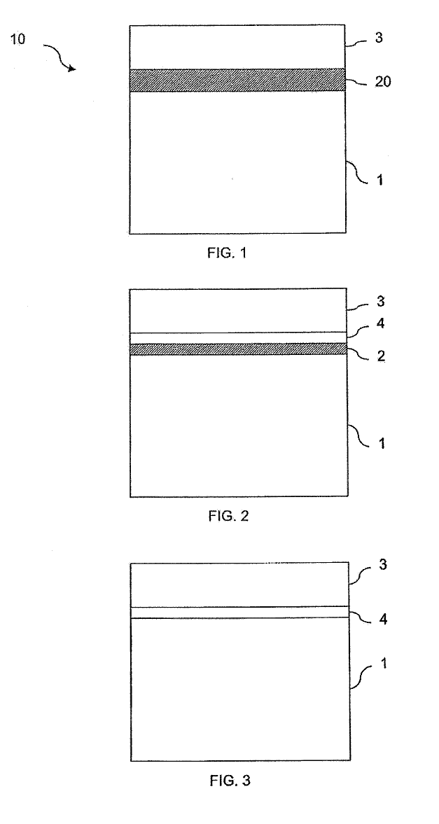

(a) the formation of an intermediate structure 10 comprising the support substrate 1, a SiO₂ layer 20 and the germanium layer 3 in direct contact with the SiO₂ layer 20. The intermediate structure 10 is illustrated in FIG. 1. Different manufacturing modes of this structure will be described in detail hereinafter.

(b) the application to said intermediate structure of a heat treatment to diffuse at least part of the oxygen of the SiO₂ layer 20, thus resulting in the total or partial dissolution of the SiO₂ layer 20.

### SiO₂ Layer Oxygen Diffusion Treatment

The Applicant defined a heat treatment which, applied under defined temperature, time and atmosphere conditions, makes it possible to diffuse all or part of the oxygen atoms from a SiO₂ layer embedded between a substrate and a germanium layer.

The heat treatment is performed by placing the GeOI intermediate structure in a furnace inside which a neutral or reducing atmosphere, for example argon, hydrogen, or a mixture of said elements, is applied.

It is important to control the residual quantity of oxygen in the atmosphere, so that it remains below a 1 ppm threshold.

To this end, it is necessary to equip the furnace with special means, such as for example insulation means from the ambient environment, at the openings.

When heating the intermediate structure, in this controlled atmosphere, to a temperature between 800 and 900° C., diffusion of the oxygen atoms through the germanium layer occurs.

Oxygen diffusion is observed from 800° C., and the oxygen diffusion rate through the germanium layer increases with the temperature.

However, as the melting point of germanium is 938° C., the heat treatment temperature must remain below this limit, and preferentially less than 900° C.

The observation of this diffusion phenomenon at a temperature as low as 800° C. was unexpected, given that oxygen diffusion from a silicon oxide layer through a thin silicon layer of an SOI only occur from a temperature of the order of 1150° C.

As the melting point of germanium is well below this temperature, the application, to a GeOI substrate, of the diffusion treatment used for an SOI, had not been previously envisaged.

This phenomenon appears to be explained by a diffusivity of oxygen in germanium considerably greater than that of the oxygen in silicon. The article by Vanhellemont et al, “Brother Silicon, Sister Germanium”, Journal of the Electrochemical Society, 154 (7) H572-H583 (2007) thus specifies that the diffusivity of oxygen in germanium is 0.4 cm² s⁻¹ whereas that of oxygen in silicon is 0.14 cm² s⁻¹.

Due to the thickness of the support substrate, the oxygen atoms are only liable to diffuse through the overlying germanium layer, and not through the substrate.

The heat treatment time is a few hours.

However, it is understood that, to enable oxygen diffusion, and particularly to obtain a sufficiently rapid and observable diffusion rate to minimise the treatment time, the thickness of the germanium layer must be less than a limit thickness.

In this way, the thickness of the germanium layer 3 of the intermediate structure 10 must be less than a few hundred nanometres, for example 500 nanometres, preferentially less than 100 nm.

The oxygen diffusion from the SiO₂ layer through the germanium layer results in the formation of a silicon layer 4, wherein the thickness increases as the treatment progresses, and a residual SiO₂ layer 2, wherein the thickness decreases conversely as the treatment progresses.

The oxygen diffusion from a 2 to 6 nm SiO₂ layer results in the formation of a 1 to 3 nm silicon layer.

The silicon layer 4 is situated between the SiO₂ layer 2 and the germanium layer 3, in contact therewith.

Indeed, the oxygen atoms situated closest to the free surface (i.e. closest to the germanium layer 3) are the first to leave the SiO₂ layer 20.

When the silicon layer 4 reaches a thickness of a few nanometres (typically, 2 to 3 nm), the diffusion phenomenon is interrupted as the oxygen atoms cannot pass through such a silicon thickness, at the treatment temperature.

If the initial thickness of the SiO₂ layer 20 is greater than a limit thickness of approximately 6 nm, the structure illustrated in FIG. 2 is obtained, successively comprising from the base to the surface thereof: the support substrate 1, a residual SiO₂ layer 2, a silicon layer 4 and the germanium layer 3. Therefore, it consists of a germanium on insulator type structure.

However, the presence of the silicon layer 4 between the germanium layer 3 and the SiO₂ layer 2 is particularly advantageous as it makes it possible to passivate the Ge/SiO₂ interface and, therefore, gives the GeOI structure enhanced electrical qualities, i.e. a reduced DIT value so as to attain the same order of magnitude as that possibly obtained for an SOI, i.e. typically of the order of 10¹¹ eV⁻¹·cm⁻²,

If the initial thickness of the SiO₂ layer 20 is less than said limit thickness, then all the oxygen contained in said layer 20 may diffuse through the germanium layer. Therefore, after the treatment, only a silicon layer 4 situated between the support substrate 1 and the germanium layer 3 remains.

This structure is illustrated in FIG. 3. In this case, the interface between the germanium layer 3 and the silicon layer 4 is conductive.

Due to the presence, in the intermediate structure, of a SiO₂ layer between the germanium layer and the support substrate, very high quality bonding between the germanium and the support substrate is obtained.

It is then possible to form, on this structure, components in or on the germanium layer, such as for example FET (field effect) or bipolar transistors.

The silicon layer 4 formed under the germanium layer 3 is very thin, making it possible to limit the appearance of crystalline defects liable to arise from the mismatching of the lattice parameter between Ge and Si.

The crystalline quality of this silicon layer 4 is greater than that of a layer that would have been formed by deposition on the germanium donor substrate, before bonding on the support substrate.

Indeed, as it is obtained after the formation of the GeOI structure, the diffusion of germanium in this layer is limited. This inter-diffusion phenomenon of germanium and silicon is generally observed when a two-layer Si—Ge structure is exposed to a certain thermal budget. In the present invention, the thermal budget applied is, on the other hand, very low. To limit this inter-diffusion phenomenon, it is possible to perform the oxygen diffusion treatment at a temperature close to the lower limit of the proposed temperature range, i.e. approximately 800° C.

### Formation of a GeOI Intermediate Structure

As seen above, the treatment in step (b) results in the total or partial dissolution of the SiO₂ layer 20 initially present under the germanium layer 3.

According to the final structure to be obtained, i.e. a GeOI structure or a structure comprising the germanium layer on a support substrate with a conductive interface, the intermediate structure will be formed with a SiO₂ layer wherein the thickness is determined to enable the partial or total diffusion of oxygen.

In this way, if it is desired to form a final structure with a conductive interface between germanium and the support substrate, an intermediate structure will be formed wherein the thickness of the SiO₂ layer is less than 6 nanometres, preferentially less than 2 nm. The oxygen diffusion heat treatment will make it possible to dissolve the SiO₂ layer completely to form a Si layer having a thickness less than 3 nm.

If, on the other hand, it is desired to obtain a GeOI type final structure, an intermediate structure will be formed wherein the thickness of the SiO₂ layer is greater than a few nanometres, preferentially greater than 6 nm. The oxygen diffusion heat treatment will then make it possible to retain a residual SiO₂ insulating layer. The initial thickness of the SiO₂ layer in the intermediate structure and the treatment conditions will be determined to obtain the desired final thickness of the insulating layer.

Three possible, but non-limitative, modes for forming the GeOI type intermediate structure 10 are described below.

### Formation of a GeOI Structure by Means of Layer Transfer (Smart Cut™)

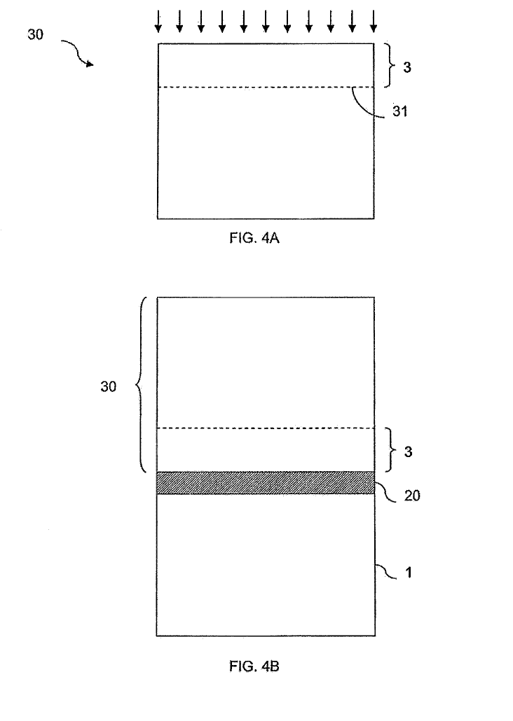

The different steps of this process are described with reference to FIGS. 4A and 4B.

FIG. 4A illustrates the formation, by means of atomic species implantation, of an embrittlement zone 31 in a donor substrate 30. The embrittlement zone thus defines the germanium layer 3 to be transferred onto the support substrate.

The donor substrate 30 may consist of bulk germanium or may be a composite substrate comprising an upper germanium layer: it may consist, as explained in the document EP 1 016 129, of a silicon substrate whereon a germanium layer has been deposited.

A SiO₂ layer is then formed on the germanium donor substrate or one the support substrate whereon the germanium layer is to be transferred.

In the first case, the formation of the SiO₂ layer is performed by means of a deposition technique.

If a SiO₂ layer is formed on the support substrate, it is possible to implement a deposition technique or a thermal oxidation, particularly if the support substrate is made of silicon.

With reference to FIG. 4B, the germanium donor substrate 30 and the support substrate 1 are placed in contact, so that the SiO₂ layer 20 is at the bonding interface.

A (thermal and/or mechanical) energy budget is then applied, resulting in the rupture of the donor substrate 30 along the embrittlement zone 31.

The GeOI type intermediate structure 10, illustrated in FIG. 1, wherein the germanium layer 3 is in direct contact with the SiO₂ layer 20, is then formed.

### Formation of a GeOI Structure by Means of Bonding Followed by Thinning

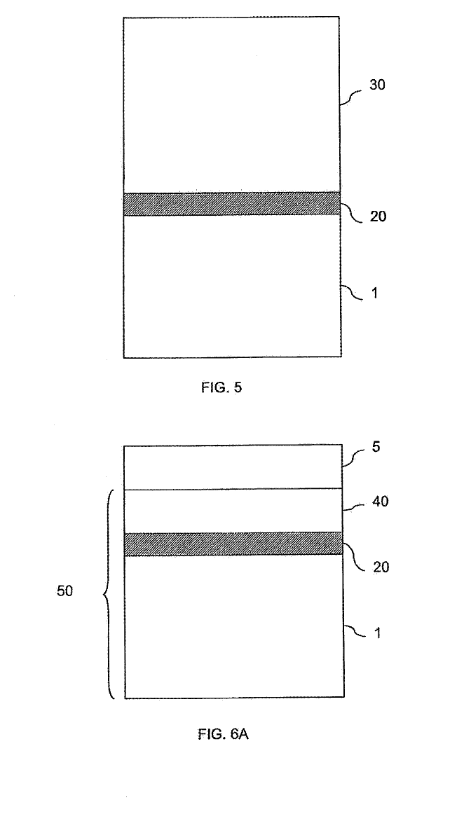

This technique comprises bonding a germanium donor substrate 30 and the support substrate 1, such that a SiO₂ layer 20 is present at the bonding interface, as illustrated in FIG. 5.

As explained above, the SiO₂ layer 20 may be formed by means of deposition on the donor substrate 30 of the support substrate 1, or obtained by means of oxidation of the support substrate 1 if said substrate is made of silicon.

It is also specified that the donor substrate may be a bulk germanium substrate or a composite substrate comprising a superficial germanium layer.

Thinning of the donor substrate 30 is then performed via the rear face thereof so as to retain only the desired thickness of the germanium layer 3. The thinning is performed by means of grinding, polishing and/or etching.

This gives the intermediate structure 10 illustrated in FIG. 1, comprising the support substrate 1, the SiO₂ layer 20 and the germanium layer 3, wherein the germanium layer 3 is in direct contact with the SiO₂ layer 20.

### Formation of a GeOI Structure by Means of a Condensation Technique

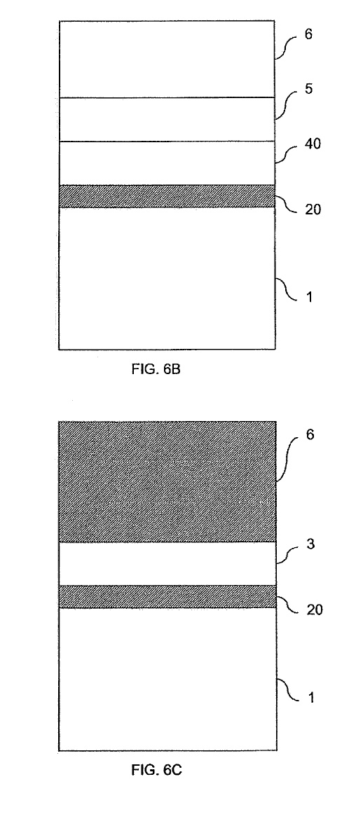

The different steps of this technique are illustrated in FIGS. 6A to 6C.

The condensation technique is described in the article entitled “Characterization of 7-nm-thick strained Ge-on-insulator layer fabricated by Ge-condensation technique” by Shu Nakaharai et al (Applied Physics Letters, Vol. 83, No. 17, 27 Oct. 2003).

With reference to FIG. 6A, by means of CVD (Chemical Vapour Deposition) epitaxy, a SiGe layer 5 is deposited on a silicon on insulator (SOI) type structure 50 successively comprising the support substrate 1, a SiO₂ insulating layer 20 and a silicon layer 40. The silicon on insulator type structure 50 is produced beforehand using any technique known to those skilled in the art, such as the Smart Cut™ process, for example.

The germanium concentration in the SiGe layer 5 is between a few percent and 50%, preferentially between 10 and 30%.

To choose the thickness of the layer 5 and the Ge concentration thereof, the preservation of the quantity of germanium will be taken into account: for example, a SiGe layer having a thickness E will give after condensation a layer comprising 100% Ge and having a thickness E/5, irrespective of the thickness of the underlying SOI.

If it is desired, in step (b), to dissolve the oxide layer under the germanium layer completely, a UT-BOX (Ultra Thin Buried OXide) type SOI, i.e. wherein the oxide layer is a few nanometres thick, will advantageously be used.

With reference to FIG. 6B, thermal oxidation of the SiGe layer 5 is performed.

The conditions of this treatment are as follows: a time of the order of one hour in an O₂ atmosphere, at a temperature less than the melting point of SiGe. The curve in FIG. 7 illustrates the melting point of SiGe as a function of the Si content. The treatment temperature must remain less than the lower curve to prevent melting of the germanium.

During this treatment, on the SiGe layer, an upper layer 6 comprising silicon and germanium is formed. However, the germanium atoms are rejected from the layer 6, while being prevented, by said layer 6 and the underlying insulating layer 20, from diffusing outside the structure.

The total quantity of germanium atoms in the SiGe layer is therefore preserved during the oxidation treatment.

Furthermore, due to inter-diffusion of Si and Ge atoms, the Si 40 and Ge 5 layer fuse to form a uniform SiGe layer, wherein the Si atoms are oxidised as the treatment progresses. The Ge fraction in the SiGe layer increases as the thickness of this layer decreases.

The process implemented in this instance is referred to as the germanium condensation technique.

This results in the structure in FIG. 6C, comprising the support substrate 1, the insulating layer 20, a Ge layer 3 in contact with the SiO₂ layer 20 and an upper SiO₂ layer 6.

The upper SiO₂ layer 6 is removed, for example by etching, by immersing the structure in a dilute HF solution. This gives the GeOI type intermediate structure 10, wherein the Ge layer 3 is in direct contact with the SiO₂ layer 20.

What is claimed is:

1. Process for manufacturing a structure comprising a germanium layer (3) on a support substrate (1), characterised in that it comprises the following steps:
(a) formation of an intermediate structure (10) comprising said support substrate (1), a silicon oxide layer (20) and said germanium layer (3), the silicon oxide layer (20) being in direct contact with the germanium layer (3),
(b) application to said intermediate structure (10) of a heat treatment, in a neutral or reducing atmosphere, at a defined temperature and for a defined time, to diffuse at least part of the oxygen from the silicon oxide layer (20) through the germanium layer (3).

2. Process according to claim 1, characterised in that the heat treatment in step (b) is performed at a temperature between 800 and 900° C.

3. Process according to any of claim 1 or 2, characterised in that the oxygen content in the atmosphere of the treatment in step (b) is less than 1 ppm.

4. Process according to any of claims 1 to 3, characterised in that the thickness of the germanium layer (3) is less than 500 nm, preferentially less than 100 nm.

5. Process according to any of claims 1 to 4, characterised in that the thickness of the silicon oxide layer (20) of the intermediate structure (10) is less than 6 nanometres, preferentially less than 2 nm, and, in step (b), all the oxygen from said layer (20) diffuses through the germanium layer (3).

6. Process according to any of claims 1 to 5, characterised in that step (a) comprises the following steps:
i) formation of the silicon oxide layer (20) on the support substrate (1) or on a germanium donor substrate (30),
ii) formation of an embrittlement zone (31) in a germanium donor substrate (31), the embrittlement zone defining the germanium layer (3) to be transferred,
iii) bonding of the germanium donor substrate (30) on the support substrate (1), the silicon oxide layer (20) being situated at the bonding interface,
iv) rupture of the germanium donor substrate (30) along the embrittlement zone (31) and transfer of the germanium layer (3) onto the support substrate (1), so as to form said intermediate structure (10).

7. Process according to any of claims 1 to 5, characterised in that step (a) comprises the following steps:
i) formation of the silicon oxide layer (20) on the support substrate (1) or on a germanium donor substrate (30),
ii) bonding of the germanium donor substrate (30) on the support substrate (1), the silicon oxide layer (20) being situated at the bonding interface,
iii) thinning of the germanium donor substrate (30) so as to retain only the thickness of the germanium layer (3), thus forming said intermediate structure (10).

8. Process according to any of claims 1 to 5, characterised in that step (a) comprises the following steps:
i) formation of a silicon on insulator type structure (50), comprising the support substrate (1), a silicon oxide layer (20) and a silicon layer (40),
ii) deposition, on the silicon layer (40) of a SiGe layer (5),
iii) application of an oxidation heat treatment of said layer (5), resulting in the formation by condensation of a germanium layer (3) on the silicon oxide layer (20) and an upper silicon oxide layer (6) on said germanium layer (3),
iv) removal of the upper silicon oxide layer (6), so as to form said intermediate structure (10).

9. Structure comprising a germanium layer (3) on a support substrate (1), characterised in that it comprises, between the support substrate (1) and the germanium layer (3), a silicon layer (4) in contact with the germanium layer (3), the silicon layer (4) having a thickness between 1 and 3 nanometres.

10. Structure according to claim 9, characterised in that it comprises, between the support substrate (1) and the silicon layer (4), a silicon oxide layer (2).
